(19) United States
(12) Patent Application Publication
(10) Pub. No.: US 2010/0020258 A1
(43) Pub. Date: Jan. 28, 2010

(54) THIN FILM TRANSISTOR SUBSTRATE, METHOD OF MANUFACTURING THEREOF AND LIQUID CRYSTAL DISPLAY DEVICE

(76) Inventor: Jae-Hyuk Chang, Seongnam-si (KR)

Correspondence Address: F. CHAU & ASSOCIATES, LLC, 130 WOODBURY ROAD, WOODBURY, NY, 11797, US

(21) Appl. No.: 12/275,601

(22) Filed: Nov. 21, 2008

(30) Foreign Application Priority Data
Jul. 22, 2008 (KR) 10-2008-0071112

(51) Int. Cl. G02F 1/136; H01L 21/336; H01L 29/04

(52) U.S. Cl. 349/46; 438/151; 257/59; 257/E29.003; 257/E21.414

(57) ABSTRACT

A method for manufacturing a thin film transistor substrate includes forming a thin film transistor array comprising gate lines, data lines and a semiconductor layer on a substrate, applying an organic layer on the thin film transistor array, pressing the organic layer with a mold comprising a prescribed pattern, removing the mold from the organic layer; and hardening the organic layer to form a passivation layer comprising a contact hole and a bank connected to the contact hole.

### CROSS-REFERENCE TO RELATED APPLICATION

This application claims priority under 35 U.S.C. §119 to Korean Patent Application No. 10-2008-0071112, filed on Jul. 22, 2008, in the Korean Intellectual Property Office (KIPO), the contents of which are incorporated herein by reference in their entirety.

### BACKGROUND OF THE INVENTION

1. Technical Field

The present invention relates to a thin film transistor substrate and a liquid crystal display device and, more particularly, to a liquid crystal display and a method for manufacturing the same in which the number of lithography process steps is reduced.

2. Discussion of the Related Art

A conventional liquid crystal display (“LCD”) includes two substrates provided with field-generating electrodes such as pixel electrodes and a common electrode, and a liquid crystal (“LC”) layer interposed therebetween. The LCD displays images by applying voltages to the field-generating electrodes to generate an electric field in the LC layer, which determines orientations of LC molecules in the LC layer to adjust polarization of incident light.

The LCD may have a layered structure including several thin films, and several photolithography processes may be employed in manufacturing the LCD panel.

However, because the photolithography processes may include complicated steps, the LCD panels can be expensive to produce. The production costs and time increase as the number of photolithography processes increase. Therefore, it is desirable to reduce the number of photolithography steps.

### SUMMARY OF THE INVENTION

A thin film transistor substrate, according to an embodiment of the present invention, includes a substrate, a thin film transistor array including gate lines, data lines and a semiconductor layer formed on the substrate, a passivation layer formed on the thin film transistor array, and a pixel electrode connected to the thin film transistor array. The passivation layer may include a contact hole and a bank connected to the contact hole.

The pixel electrode may be formed in the bank and connected to the thin film transistor array through the contact hole. A top surface extending from the passivation layer to the pixel electrode may be flat. The passivation layer further may include a column spacer.

A dielectric layer may be formed between the passivation layer and the thin film transistor array. The dielectric layer may include an aperture corresponding to the contact hole.

A method for manufacturing a thin film transistor substrate, according to an embodiment of the present invention, includes forming a thin film transistor array including gate lines, data lines and a semiconductor layer on a substrate, applying an organic layer on the thin film transistor array, pressing the organic layer with a mold including a prescribed pattern, removing the mold from the organic layer, hardening the organic layer, and forming a passivation layer including a contact hole and a bank connected to the contact hole.

The mold may include a first projection to form the contact hole and a second projection to form the bank. The first projection may be connected to the second projection. The passivation layer may further include a column spacer. The mold may include a depression to form the column spacer.

The pixel electrode may be connected to the thin film transistor array through the contact hole.

A top surface extending from the passivation layer to the pixel electrode may be flat.

The pixel electrode may be formed by an inkjet process.

The method may further include forming a dielectric layer on the thin film transistor array before applying the organic layer.

The method may further include removing a portion of the dielectric layer by an etching process after removing the mold.

A liquid crystal display, according to an embodiment of the present invention, includes a first substrate, a thin film transistor array including gate lines, data lines and a semiconductor layer formed on the first substrate, a passivation layer formed on the thin film transistor array, a first electrode connected to the thin film transistor array, a second substrate facing the first substrate, a second electrode formed on the second substrate, and a liquid crystal layer formed between the first substrate and second substrate.

The passivation layer may include a contact hole and a bank connected to the contact hole. The first electrode may be formed in the bank and connected to the thin film transistor array through the contact hole.

A top surface extending from the passivation layer to the first electrode may be flat.

The liquid crystal display may further include a column spacer formed on the passivation layer and supporting an interval between the first substrate and the second substrate.

The column spacer and the passivation layer may be made of the same layer and of substantially the same material.

The contact hole, the bank and the column spacer may be formed by patterning the passivation layer using a mold. The column spacer may be a continuous extension of the passivation layer.

The liquid crystal display may further include a dielectric layer formed between the thin film transistor array and the passivation layer.

The dielectric layer includes an aperture corresponding to the contact hole.

The liquid crystal display may further include a color filter array formed on the second substrate and the second electrode.

### BRIEF DESCRIPTION OF THE DRAWINGS

Exemplary embodiments of the present invention can be understood in more detail from the following descriptions taken in conjunction with the accompanying drawings in which:

FIG. 1 is a layout view of an LCD according to an embodiment of the present invention;

FIG. 2 is cross-a sectional view of the LCD shown in FIG. 1 taken along line I-I′, according to an embodiment of the present invention;

FIGS. 3A to 3G are sectional views of a thin film transistor (TFT) substrate of an LCD in steps of a manufacturing method according to an embodiment of the present invention;

FIGS. 4 is a cross-sectional view of the LCD shown in FIG. 1 taken along the line I-I′ according to an embodiment of the present invention; and

FIGS. 5A to 5F are sectional views of a TFT substrate of an LCD in steps of a manufacturing method according to an embodiment of the present invention.

### DETAILED DESCRIPTION OF EXEMPLARY EMBODIMENTS

Exemplary embodiments of the present invention now will be described more fully hereinafter with reference to the accompanying drawings, in which exemplary embodiments of the invention are shown. The present invention may, however, be embodied in many different forms and should not be construed as limited to the embodiments set forth herein. Like numerals refer to like elements throughout.

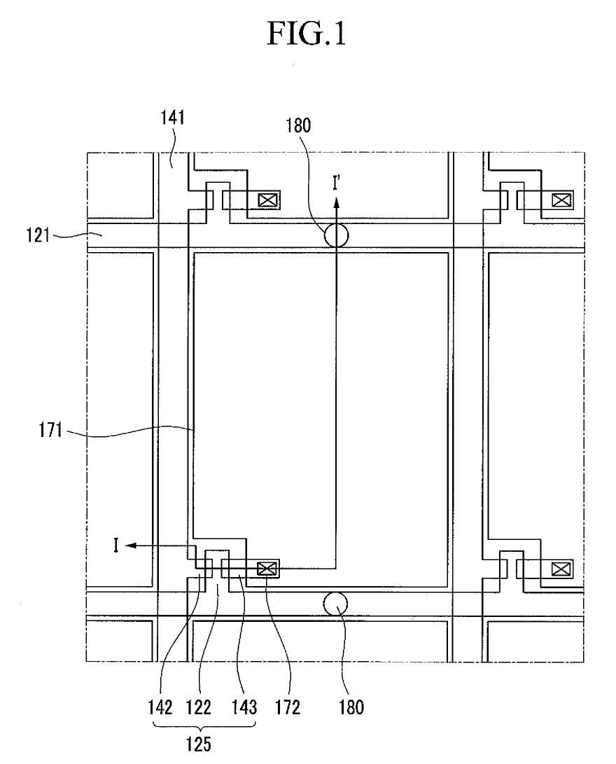

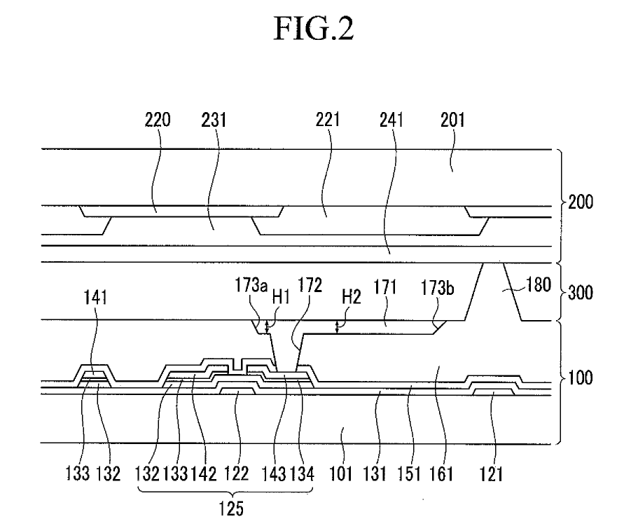

An LCD according to an embodiment of the present invention will be described in detail with reference to FIGS. 1-2. FIG. 1 is a layout view of an LCD according to an embodiment of the present invention and FIG. 2 is cross-a sectional view of the LCD shown in FIG. 1 taken along line I-I′.

Referring to FIGS. 1-2, an LCD according to an embodiment of the present invention includes a thin film transistor (TFT) substrate 100, a common electrode substrate 200, and an LC layer 300 interposed between the TFT substrate and common electrode substrate 100 and 200.

A plurality of gate lines 121 are formed on an insulating substrate 101 made of a material such as transparent glass or plastic.

The gate lines 121 extend substantially in a transverse direction, are separated from each other and transmit gate signals. Each gate line 121 includes a plurality of projections forming a plurality of gate electrodes 122.

The gate lines 121 are formed of an Al-containing metal such as Al and an Al alloy, a Ag-containing metal such as Ag and a Ag alloy, a Cu-containing metal such as Cu and a Cu alloy, a Mo-containing metal such as Mo and a Mo alloy, Cr, Ta, or Ti. The gate lines 121 may have a multi-layered structure including two conductive films (not shown) having different physical characteristics. One of the two conductive films is formed of a low resistivity metal including, for example, an Al-containing metal, an Ag-containing metal, and/or a Cu-containing metal for reducing signal delay or voltage drop. The other conductive film is made of, for example, a material such as a Mo-containing metal, Cr, Ta, or Ti, which has good physical, chemical, and electrical contact characteristics with other materials such as indium tin oxide (ITO) or indium zinc oxide (IZO). Examples of the combination are a lower Mo film, an intermediate Al film, and an upper Mo film, or a lower Cr film and an upper Al—Nd alloy film and a lower Al film and an upper Mo film. However, the gate lines may be made of various metals or conductors.

In addition, the lateral sides of the gate lines 121 are inclined relative to a surface of the substrate, and the inclination angle thereof ranges from about 30 degrees to about 80 degrees.

A gate insulating layer 131 may be made of silicon nitride (SiNx) and is formed on the gate lines 121.

A plurality of semiconductor layers 132 are formed of hydrogenated amorphous silicon (a-Si:H) or polysilicon and are formed on the gate insulating layer 131.

A plurality of ohmic contact layers 133 and 134 are formed on the semiconductor layers 132. The ohmic contact layers 133 and 134 are made of n+ hydrogenated a-Si heavily doped with an n-type impurity such as phosphorous, or the ohmic contact layers 133 and 134 may be made of silicide.

The lateral sides of the semiconductor layers 132 and the ohmic contact layers 133 and 134 are tapered, and the inclination angles thereof range from about 30 degrees to about 80 degrees.

A plurality of data lines 141 include a plurality of source electrodes 142 projecting therefrom. Drain electrodes 143 are separated from the data lines 141 and source electrodes 142. The source and drain electrodes 142, 143 are formed on the ohmic contact layers 133 and 134 and the gate insulating layer 131.

The data lines 141 for transmitting data voltages extend substantially in the longitudinal direction and cross the gate lines 121 at right angles. Each data line 141 includes a plurality of source electrodes 142 projecting toward the drain electrodes 143.

A gate electrode 122, a source electrode 142, a drain electrode 143, a semiconductor layer 132 and an ohmic contact layers 133 and 134 form a TFT having a channel disposed between the source electrode 142 and the drain electrode 143.

The data lines 141 (including the source electrode 142) and the drain electrodes 143 may be made of a refractory metal such as Cr, Mo, Ti, Ta, or alloys thereof. The data lines 141 and source and drain electrodes 142, 143 may also have a multilayered structure including a low-resistivity film (not shown) and a good-contact film (not shown). Examples of the combination are a lower Mo film, an intermediate Al film, and an upper Mo film, or a lower Cr film and an upper Al—Nd alloy film and a lower Al film and an upper Mo film. The data lines 141 and the source and drain electrodes 142, 143 may be made of various metals or conductors.

Like the gate lines 121, the data lines 141 and the source and drain electrodes 142, 143 have tapered lateral sides, and the inclination angles thereof range from about 30 degrees to about 80 degrees.

A dielectric layer 151, made of an inorganic insulator, is formed on the insulating substrate 101, the gate lines 121, the data lines 141, the source and drain electrodes 142, 143 and the semiconductor layer 132. Examples of the inorganic insulator include silicon nitride (SiNx) or silicon oxide (SiOx).

A passivation layer 161, made of, for example, an organic insulator, is formed on the dielectric layer 151. The organic insulator may have photosensitivity and a dielectric constant less than about 4.0.

The passivation layer 161 includes a plurality of contact holes 172 exposing the drain electrode 143, and a plurality of banks 173a, 173b connected to the contact holes 172.

A plurality of column spacers 180 are formed on the passivation layer 161. The columnar spacers 180 may be made of the same layer as the passivation layer 161, and may be made of the same material as that of the passivation layer 161. The columnar spacers 180 may be integral with and extend from the passivation layer 161.

The column spacers 180 support the interval between the TFT substrate 100 and the common electrode substrate 200 along with the passivation layer 161. The column spacers 180 are formed on a portion of the passivation layer 161 which is formed on the gate lines 121. However, the column spacers 180 may be formed on a portion of the passivation layer 161 which is formed on the data lines 141. Also, the column spacers 180 may be formed on a portion of the passivation layer 161 which is formed on an intersection of the gate lines 121 and the data lines 141. A plurality of pixel electrodes 171 are formed in the banks 173a, 173b and connected to the thin film transistor array 125 through the contact hole 172. Height (H1) of the banks 173a, 173b may be the same as a height (H2) of the pixel electrode. A top surface of the passivation layer 161 and the pixel electrodes 171 may be flat without a grade, wherein the top surface extending from the passivation layer 161 to the pixel electrode 171 is flat such that the top surfaces of the pixel electrode 171 and the passivation layer 161 are in the same plane. The pixel electrodes 171 are made of a transparent conductor such as ITO or IZO or a reflective conductor such as Ag or Al. The pixel electrodes 171 are physically and electrically connected to the drain electrodes 143 through the contact holes 172 such that the pixel electrodes 171 receive the data voltages from the drain electrodes 143. The pixel electrodes 171 supplied with the data voltages generate electric fields in cooperation with the common electrode 241, which determine orientations of liquid crystal molecules (not shown) in the liquid crystal (LC) layer 300. A description of the common electrode substrate 200 follows with reference to FIGS. 1 and 2. A light-blocking member 220 called a black matrix for preventing light leakage is formed on an insulating substrate 201 made of a material such as transparent glass or plastic. A plurality of color filters 221 are formed on the insulating substrate 201 and are disposed substantially in the areas enclosed by the light-blocking member 220. The color filters 221 may extend substantially in the longitudinal direction along the pixel column such that they may be stripe shaped. The color filters 221 may respectively represent one of the primary colors such as red, green, or blue colors. An overcoat 231 for preventing the color filters 221 from being exposed and for providing a flat surface is formed on the color filters 221 and the light-blocking member 220. The overcoat 231 may be omitted. A common electrode 241, made of, for example, a transparent conductive material such as ITO and IZO, is formed on the overcoat 231.

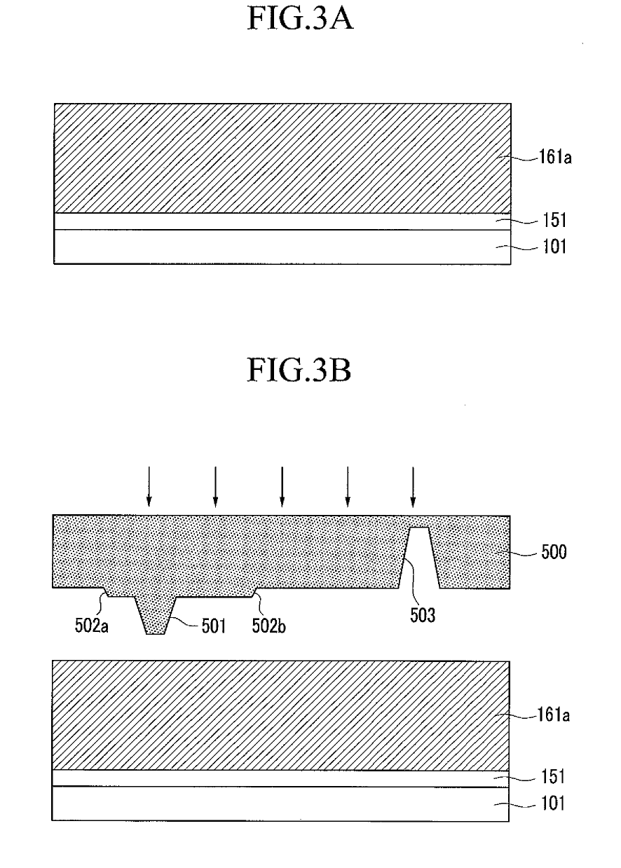

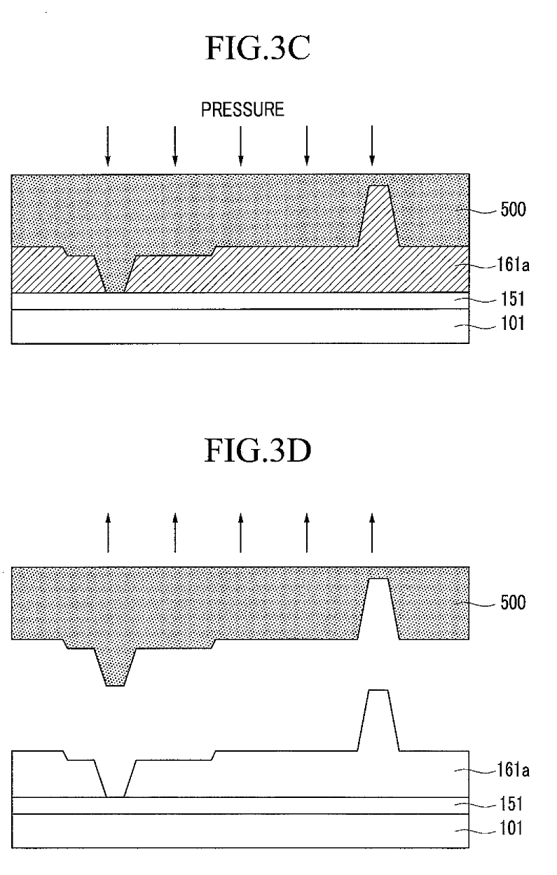

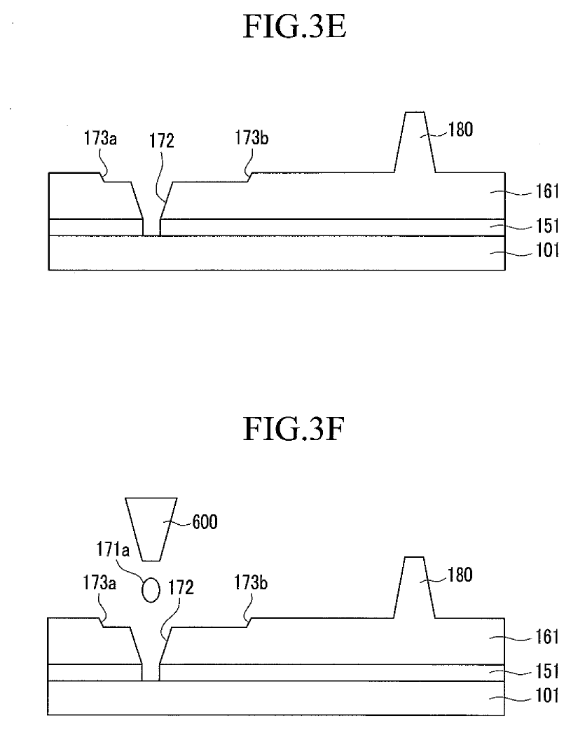

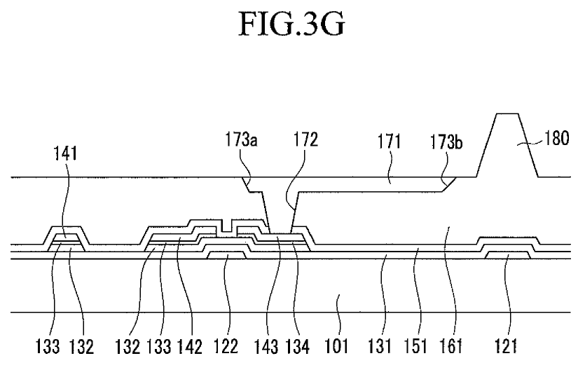

A manufacturing method for forming the passivation layer 161, the banks 173a, 173b and the column spacer 180 is described for an LCD according to an embodiment of the present invention, with reference to FIGS. 3A to 3G. FIGS. 3A to 3G are sectional views of a thin film transistor (TFT) substrate of an LCD in steps of a manufacturing method according to an embodiment of the present invention. As shown in FIG. 3A, an organic insulating layer 161a is coated on an insulating substrate 101 including a TFT array (not shown) and a dielectric layer 151.

As shown in FIG. 3B, a mold 500 having a first projection 501 corresponding to the contact hole 172 (FIGS. 1, 2), a second projection including portions 502a and 502b respectively corresponding to the banks 173a, 173b (FIGS. 2) and a depression 503 corresponding to the column spacer 180 (FIGS. 1, 2) is aligned with the organic insulating layer 161a and is pressed on the organic insulating layer 180a as shown in FIG. 3C. The mold 500 may be formed of polyurethanacrylate (PUA), and the organic insulating layer 161a may include a thermal hardening resin. As shown in FIG. 3D, the mold 500 is removed from the organic insulating layer 161a and the organic insulating layer 161a is hardened by heating. An ashing process may be further performed when the organic insulating layer 161a corresponding to the contact hole is not removed fully by the mold 500. An oxygen gas may be used in the ashing process. The dielectric layer 151 exposed by the first projection 501 of the mold 500 is dry-etched to complete the contact hole 172, as shown in FIG. 3E, and the passivation layer 161 including the contact hole 172, the banks 173a, 173b and the column spacers 180 is formed on the dielectric layer 151 and the insulation substrate 101.

As shown in FIG. 3F and FIG. 3G, a conductive material 171a for forming a pixel electrode 171 supplied from an inkjet head 600 is applied on the contact hole 172 and the banks 173a, 173b. The banks 173a, 173b may prevent the conductive material 171a from overflowing into adjacent pixels when the conductive material 171a is applied. A top surface of the passivation layer 161 and the pixel electrodes 171 may be flat without a grade, wherein the top surface extending from the passivation layer 161 to the pixel electrode 171 is flat such that the top surfaces of the pixel electrode 171 and the passivation layer 161 are in the same plane.

According to an embodiment of the present invention, the passivation layer 161, the contact holes 172, the banks 173a, 173b and the column spacer 180 may be simultaneously formed by the process using the mold 500. The process is more effective than a photolithography process using a mask for forming the passivation layer 161, and more particularly, the process may reduce production time and costs for manufacturing the LCD by omitting an exposure step and a developing step.

Accordingly the cost of materials for forming the passivation layer 161 is lower and the deposition of the materials is simplified.

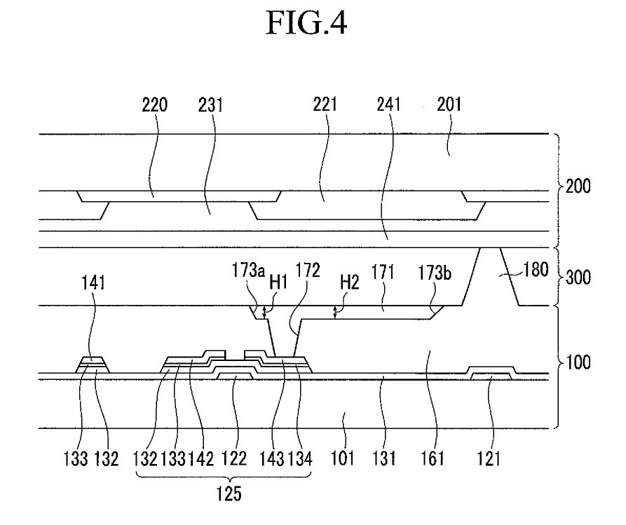

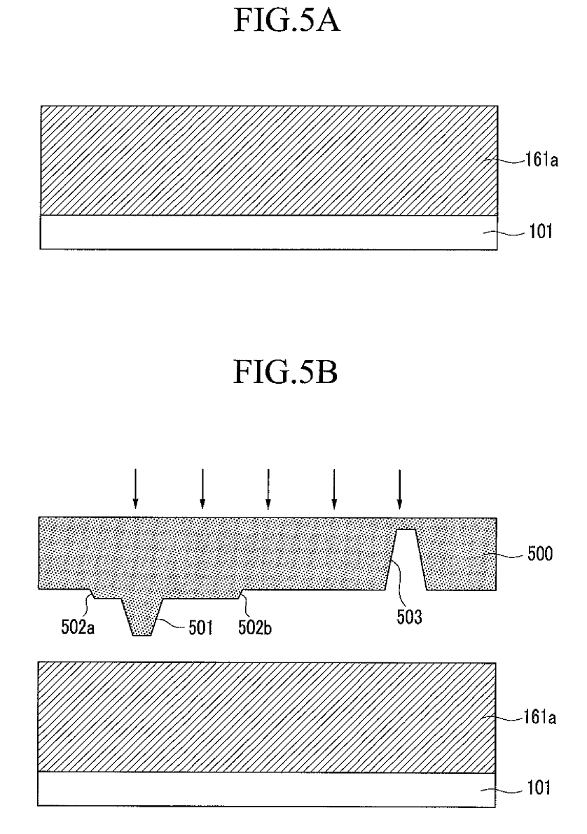

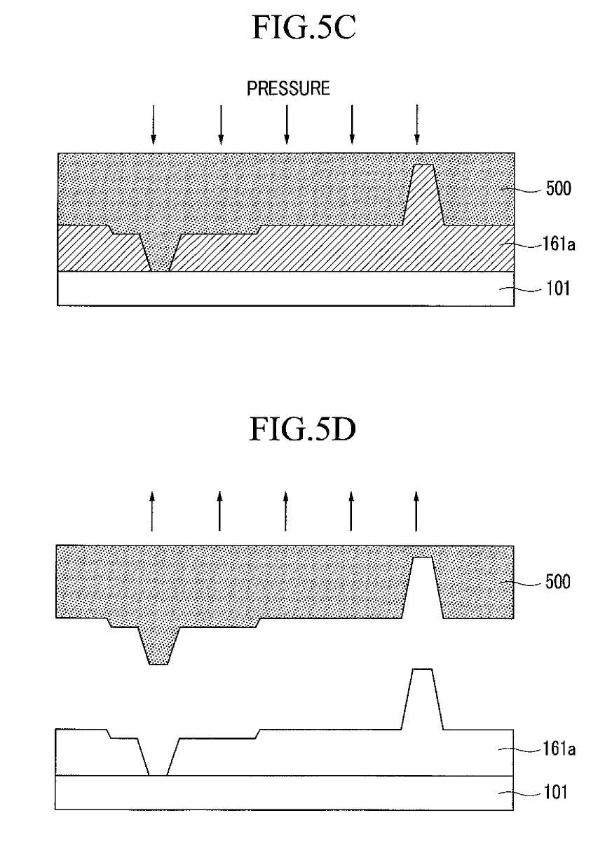

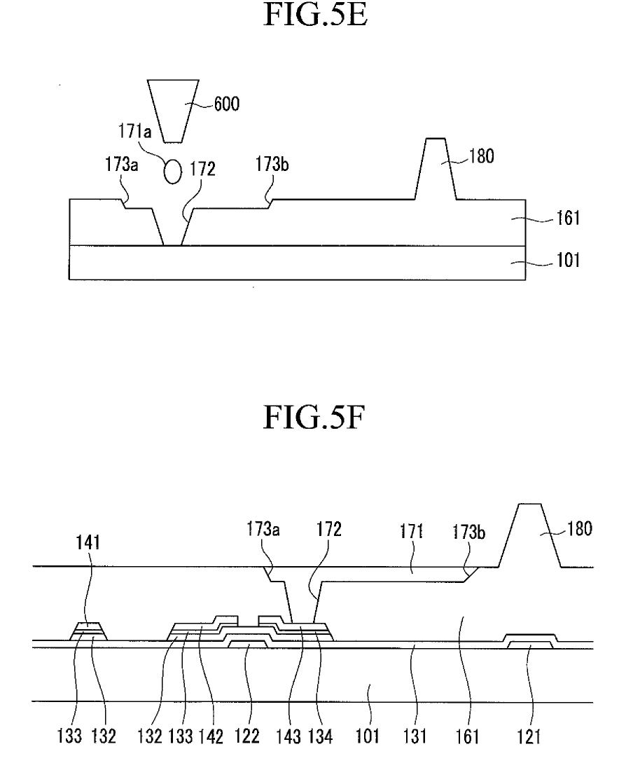

The manufacturing method for forming the passivation layer 161, the banks 173a, 173b and the columnar spacer 180 is described for an LCD according to an embodiment of the present invention, with reference to FIG. 4 and FIGS. 5A to 5F.

FIG. 4 is a cross-sectional view of the LCD shown in FIG. 1 taken along the line I-I′ according to an embodiment of the present invention.

FIGS. 5A to 5F are sectional views of a TFT substrate of an LCD in steps of a manufacturing method according to an embodiment of the present invention.

As shown in FIG. 4, a TFT substrate 100 includes an insulating substrate 101, a TFT array 125, and a passivation layer 161 including a contact hole 172, banks 173a, 173b and a column spacer 180. However, a dielectric layer 151 (FIG. 2) is not formed on TFT array 125.

A common electrode substrate 200 includes an insulating layer 201, a light-blocking member 220, a color filter 221, an overcoat 231 and a common electrode 241.

With the exception of the lack of the dielectric layer 151, the above structures are the same as the LCD in accordance with the embodiment of the present invention is described in detail with respect to FIG. 2. Therefore, a repetitive description is omitted.

As shown in FIG. 5A, an organic insulating layer 161a is coated on an insulating substrate 101 including a TFT array (not shown).

As shown in FIG. 5B, a mold 500 having a first projection 501 corresponding to the contact hole 172 (FIGS. 1, 4), a second projection including portions 502a, 502b respectively corresponding to the banks 173a, 173b (FIG. 4) and a depression 503 corresponding to the column spacer 180 (FIGS. 1, 4) is aligned with the organic insulating layer 161a and is pressed on the organic insulating layer 161a as shown in FIG. 5C. The mold 500 may be formed of PUA, and the organic insulating layer 161a may include a thermal hardening resin. The organic insulating layer 161a may include a material which discharges a small amount of gas into the TFT array and has low shrinkage after being hardened.

As shown in FIG. 5D, the mold 500 is removed from the organic insulating layer 161a and the organic insulating layer 161a is hardened by heating. An ashing process may be further performed when the organic insulating layer 161a corresponding to the contact hole is not removed fully by the mold 500. An oxygen gas may be used in the ashing process.

As shown in FIGS. 5E and FIG. 5F, a conductive material 171a for forming a pixel electrode 171 supplied from an inkjet head 600 is applied on the contact hole 172 and the banks 173a, 173b. The banks 173a, 173b may prevent the conductive material 171a from overflowing into adjacent pixels when the conductive material 171a is applied. A top surface of the passivation layer 161 and the pixel electrodes 171 may be flat without a grade, wherein the top surface extending from the passivation layer 161 to the pixel electrode 171 is flat such that the top surfaces of the pixel electrode 171 and the passivation layer 161 are in the same plane.

According to an embodiment of the present invention, a process for forming a dielectric layer on TFT array may be omitted.

Also, the passivation layer 161, the contact holes 172, the banks 173a, 173b and the column spacer 180 may be simultaneously formed by the process using the mold 500. The process is more effective than a photolithography process using a mask for forming the passivation layer 161, and more particularly, the process may reduce production time and costs for manufacturing the LCD by omitting an exposure step and a developing step.

Accordingly, the cost of materials for forming the passivation layer 161 is lower and the deposition of the materials is simplified.

While the present invention has been described in detail with reference to the preferred embodiments, those skilled in the art will appreciate that various modifications and substitutions can be made thereto without departing from the spirit and scope of the present invention as set forth in the appended claims.

What is claimed is:

1. A thin film transistor substrate, comprising:
a substrate;
a thin film transistor array comprising gate lines, data lines and a semiconductor layer on the substrate;
a passivation layer on the thin film transistor array, the passivation layer comprising a contact hole and a bank connected to the contact hole; and
a pixel electrode connected to the thin film transistor array through the contact hole.

2. The thin film transistor substrate of claim 1, wherein the pixel electrode is positioned in the bank.

3. The thin film transistor substrate of claim 2, wherein a top surface extending from the passivation layer to the pixel electrode is flat.

4. The thin film transistor substrate of claim 1, wherein the passivation layer further comprises a columnar spacer.

5. The thin film transistor substrate of claim 1, further comprising a dielectric layer formed between the passivation layer and the thin film transistor array.

6. The thin film transistor substrate of claim 5, wherein the dielectric layer comprises an aperture corresponding to the contact hole.

7. A method for manufacturing a thin film transistor substrate, the method comprising:
forming a thin film transistor array comprising gate lines, data lines and a semiconductor layer on a substrate;
applying an organic layer on the thin film transistor array;
pressing the organic layer with a mold comprising a prescribed pattern;
removing the mold from the organic layer; and
hardening the organic layer to form a passivation layer comprising a contact hole and a bank connected to the contact hole.

8. The method of claim 7, wherein the mold comprises a first projection to form the contact hole and a second projection to form the bank.

9. The method of claim 8, wherein the first projection is connected to the second projection.

10. The method of claim 8, wherein the passivation layer further comprises a column spacer.

11. The method of claim 10, wherein the mold comprises a depression to form the column spacer.

12. The method of claim 7, further comprising forming a pixel electrode in the bank, wherein the pixel electrode is connected to the thin film transistor array through the contact hole.

13. The method of claim 12, wherein a top surface extending from the passivation layer to the pixel electrode is flat.

14. The method of claim 13, wherein the pixel electrode is formed by an inkjet process.

15. The method of claim 7, further comprising forming a dielectric layer on the thin film transistor array before applying the organic layer.

16. The method of claim 15, further comprising removing a portion of the dielectric layer by an etching process after removing the mold.

17. A liquid crystal display, comprising:
a first substrate;
a thin film transistor array comprising gate lines, data lines and a semiconductor layer on the first substrate;
a passivation layer on the thin film transistor array, the passivation layer comprising a contact hole and a bank connected to the contact hole;
a first electrode connected to the thin film transistor array through the contact hole;
a second substrate facing the first substrate;
a second electrode on the second substrate; and
a liquid crystal layer between the first substrate and second substrate.

18. The liquid crystal display of claim 17, wherein the first electrode is positioned in the bank.

19. The liquid crystal display of claim 18, wherein a top surface extending from the passivation layer to the first electrode is flat.

20. The liquid crystal display of claim 17, further comprising a column spacer on the passivation layer and supporting an interval between the first substrate and the second substrate.

21. The liquid crystal display of claim 20, wherein the column spacer and the passivation layer are made of the same layer and of substantially the same material.

22. The liquid crystal display of claim 21, wherein the the column spacer continuously extends from the passivation layer.

23. The liquid crystal display of claim 17, further comprising a dielectric layer formed between the thin film transistor array and the passivation layer.

24. The liquid crystal display of claim 23, wherein the dielectric layer comprises an aperture corresponding to the contact hole.

25. The liquid crystal display of claim 17, further comprising a color filter array on the second substrate and the second electrode.
